(19) United States
(12) Patent Application Publication
(10) Pub. No.: US 2004/0241556 A1
(43) Pub. Date: Dec. 2, 2004

(54) Mask, mask blank, photosensitive film therefor and fabrication thereof

(76) Inventors: Robert A. Bellman, Painted Post, NY (US); Nicholas F. Borrelli, Elmira, NY (US); Robin M. Walton, Painted Post, NY (US)

Correspondence Address: CORNING INCORPORATED, SP-TI-3-1, CORNING, NY, 14831

(21) Appl. No.: 10/448,681

(22) Filed: May 29, 2003

(51) Int. Cl. G03C 5/00; B32B 9/00; G03F 9/00; B32B 17/06

(52) U.S. Cl. 430/5; 430/322; 428/428; 430/323; 430/324

(57) ABSTRACT

Disclosed are masks and mask blanks for photolithographic processes, photosensitive films and fabrication method therefor. Photosensitive films are deposited on a substrate in the masks for recording permanent pattern features via UV exposure. The masks are advantageously phase-shifting, but can be gray-scale masks having index patterns with arbitrary distribution of refractive index and pattern depth. The masks may have features above the surface formed from opaque or attenuating materials. Boro-germano-silicate photosensitive films having a composition consisting essentially, in terms of mole percentage, of: 0-20% of B₂O₃, 5-25% of GeO₂ and the remainder SiO₂ can be used for the film. The film is advantageously deposited by using PECVD wherein tetramethoxygermane is used as the germanium source.

### FIELD OF THE INVENTION

The present invention relates to mask and mask blank, photosensitive film therefor and fabrication thereof. In particular, the present invention relates to UV photosensitive films, photolithographic mask and mask blank comprising such photosensitive film and fabrication method therefor. The present invention is useful, for example, in the fabrication of phase-shifting photomasks and grayscale photomasks.

### BACKGROUND OF THE INVENTION

Photolithography is the process used by semiconductor chip manufacturers to transfer integrated circuit patterns through a mask onto a silicon wafer. An exemplary traditional binary mask is a fused quartz plate, with an opaque Cr film on it. Openings in the mask, corresponding to the IC features, allow light from an optical projection system (called a stepper because the exposure is a step and repeat process) to irradiate a photosensitive polymer (photoresist) layer coated on the silicon wafer. After resist development, or its selective removal (positive resist) in the pattern of the circuit design, the silicon is now exposed to allow etching, metal deposition, ion implantation or other processing, followed by removal or “stripping” of the photoresist. To make a modern, complex microprocessor or memory chip requires as many as 20 iterations of this process with different but complementary (and critically aligned) masks (or mask set). One limitation of photolithography is that there is a minimum feature size that can be imaged on the wafer, determined by the optics of the stepper, the wavelength of the imaging light, and the particular process (e.g., contrast of the photoresist material). As the minimum feature size is reduced, speed and density in chips increase as does the cost of the photolithography tool substantially. Fortunately, a number of strategies have been developed to extend the usefulness of any optical lithography generation. One of these optical extensions is the phase-shifting mask. It can enhance resolution beyond the wavelength-imposed diffraction limit. Since some fraction of the light used in lithography is coherent, phase-shifting masks work by destructive optical interference to enhance imaging contrast.

The resolution of an image formed by a projection stepper in a photolithography system is defined by the following equation:

R=k₁·(λ/NA) (1)

wherein R is resolution, k₁ is process-dependent constant, λ is the illumination wavelength, and NA=sin θ is numerical aperture of the projection lens. Depth of focus (DoF) is another important parameter of a photolithography process besides resolution R. Usually a large DoF is desired, because a larger DoF renders the process more tolerant to departure in wafer flatness and photoresist thickness uniformity. DoF is determined according to the following equation:

DoF=k₂·(λ/NA²) (2)

where k₂ is another process-dependent constant.

From these above equations (1) and (2), it can be seen that, in order to enhance resolution R, the following approaches may be employed (i) using a shorter illumination wavelength λ; (ii) using a projection system having larger numerical aperture NA; or (iii) lower constant k₁ by improving the process such as by using photo-shifting mask or a higher contrast photoresist. Phase-shifting masks can improve resolution without sacrificing DoF. Since optical interference does not depend critically upon a perfectly focused image, phase-shift masks can actually increase DoF in comparison to traditional Cr masks. Two types of phase-shifting masks are commonly used in lithograph: alternating aperture phase-shifting masks and the embedded attenuating phase-shifting mask. FIG. 1 compares the imaging process for a traditional Cr binary mask and a simple form of the alternating aperture phase-shifting mask. Each mask has two closely spaced openings. Because the imaging light is an electromagnetic wave, it has both an electric field amplitude and a phase; the radiance or dose needed to expose the photoresist is proportional to the square of this amplitude. When light passes through adjacent apertures in the Cr mask, the amplitude profiles broaden due to diffraction and spatial filtering of the optical system. At the wafer, the electric field amplitude overlap and interfere constructively because the light is at least partially coherent. At the wafer, the intensity of the light, which is proportional to the total amplitude squared, is large everywhere and the resist will also be exposed between the apertures, blurring the separate features together. In the simple phase-shift mask, light that traverses one of the apertures is phase-shifted 180°. Again the electric field amplitudes of light passing through the two apertures broaden, but because one component is phase-shifted 180°, they interfere destructively, such that the net amplitude of the imaging light becomes zero (or dark) between adjacent apertures or features. The light intensity passing through the separate apertures is now resolved at the wafer and therefore resolution of imaged features is enhanced.

The alternating aperture phase-shifting mask is particularly well suited for printing closely spaced lines. Typically, it provides a 50% improvement in resolution compared to traditional binary Cr masks. In a conventional practical mask design, the quartz substrate is etched to produce the 180° phase-shift masks, especially when the features to be printed are in complicated circuit patterns. An unwanted result is that the abrupt transition between 0° and 180° always prints as a dark line, and it can bridge or short circuit isolated lines in some circuit designs. Although there are strategies to circumvent this, implementing them adds complexity to the mask design, especially for intricate circuits.

FIGS. 2A, 2B and 2C shows plan, side elevation (along line A) and end elevation (along line B) views of the result of steps in construction of an alternating aperture PSM as currently implemented commercially. A substrate 10 is made of a material such as a fused quartz plate or other stable material which must be transparent to the light used in the photolithography for a transmission mask. The substrate 10 coated with an opaque (“chrome”) film 12 in which openings 14 and 16 have been opened by normal photoresist application, exposure and development, followed by chrome etch to form a conventional chrome-on-glass (COG) photomask. After stripping the original photoresist, the photomask is then recoated with a resist film and apertures are opened in the resist film at the locations of apertures which will be phase-shifted. The openings in this second resist film are larger than those in the underlying chrome to accommodate possible mis-registration. The photomask is then etched and the chrome 12 exposed in the resist openings is used as a mask to etch the underlying substrate 10 to a depth below the original surface to make the depressions after the etching of the substrate 10. The depth of the features etched in the substrate 10 is carefully chosen on the basis of the wavelength of the light to be used in the photolithography and the difference in the index of refraction of the material of the substrate and the ambient atmosphere in which the phase-shifting mask is used.

The other type of phase-shifting mask is the embedded attenuating phase-shifting mask (EAPSM). It is schematically illustrated in FIG. 3A. This mask allows some (typically 6-18%) of the imaging illumination, phase-shifted 180°, to be transmitted by the mask in the normally opaque areas of a corresponding Cr binary mask. In this case, the diffraction of light that passes through an opening in the mask. Again, even though the out of phase electric field amplitude is only a fraction of the non-shifted light amplitude passing though the aperture, their profiles interfere destructively (net amplitude is zero between apertures) and sharper contrast and improvement in DoF is achieved in imaging. While attenuating phase-shift masks do not afford as much resolution enhancement as the fully transparent alternating aperture masks, they can be fabricated to work for complex circuit patterns using conventional mask making techniques, making them attractive for replacement of Cr binary masks when printing features with sub-wavelength resolution. EAPSMs are particularly suited for printing contacts and isolated clear circuit features with special off-axis illumination. The production of the EAPSMs involves multiple steps of resist deposition, exposure, development, stripping, as well as deposition and etching of Cr and phase shift thin films. FIG. 3B illustrates schematically the steps for producing a typical EAPSM using TiSiN as the attenuating phase-shifting material.

Chromeless phase-shifting mask has been developed recently in chromeless phase lithography (CPL). CPL uses chromeless features on the masks to define patterns that have nearly 100% transmission and are phase shifted by 180°. FIG. 4 is a schematic illustration of how a chromeless mask functions. The phase shift is created by etching the quartz substrate of the mask to a depth that is dependent on the wavelength of the imaging system. Using the etched quartz to induce a phase shift, it is possible to build the desired 100% transmission phase structures for any given wavelength using standard chrome on quartz substrates. CPL of this type usually requires a higher NA and a strong off-axis illumination in order to form the high contrast aerial images.

In the production of all of the prior art phase-shifting masks, very complex multi-step resist deposition, exposure, development and stripping are required. And the resulted phase-shifting mask has an uneven surface even when no Cr layer is applied. This is because the phase shift effect is caused by an additional thin film having a differing refractive index than the substrate or by varying thickness of the substrate. In the prior art phase-shifting masks, in order to obtain a near 180° phase shift, the following requirement must be met:

d·(nₛ−1)≈λ/2 (3)

where d is the thickness of the phase shift film deposited on top of the substrate, or the height of the phase shift steps in a chromeless phase-shifting mask, nₛ is the refractive index of the phase shift film or the substrate in a chromeless phase-shifting mask, and λ is the illumination wavelength.

The phase shifting approach offers great resolution improvement with 25 nm gate length silicon-on-insulator (SOI) devices using a 248-nm stepper. This method has a deep subwavelength potential. SOI transistors with polysilicon gate lengths of 90, 25 and 9 nm have been demonstrated manufacturable by this approach using a 248-nm stepper. However, for the reasons mentioned above, this approach has so far suffered from impediments such as high mask cost, long turnaround time and difficult inspectability/repair.

Therefore, there remains a genuine need of a phase-shifting mask that overcomes the drawbacks of the current phase-shifting masks described above.

### SUMMARY OF THE INVENTION

The present inventors have discovered a photosensitive film, which, upon exposure to certain radiation, has an induced refractive index change. The film can be used in the production of phase shift photomasks. By selectively exposing the film to radiation, patterns of material having differing refractive index than that of the original film can be created within the film. A near 180° phase shift can be effected if the following condition is met:

d·(n₁−n₀)≈λ/2 (4)

where d is the thickness of the exposed area of the film with an induced refractive index, n₁ is the refractive index of the material with induced refractive index change after exposure, and n₀ is the refractive index of the material without induced refractive index change. Because of the photosensitive property, this film can be used in photomasks in the field of microlithography for the manufacture of integrated circuits, magnetic devices and other micro-devices such as micro-machines. Manufacture of masks, especially phase-shifting masks based on substrates bearing the photosensitive films is less complex than conventional phase-shifting masks.

Accordingly, a first aspect of the present invention is a mask for use in microlithography for the manufacture of integrated circuits, magnetic devices, and other micro-devices such as micro-machines. The mask of the present invention has a pattern P₀ transferable onto a image-receiving substrate when subjected to illumination radiation in a lithographic process, comprises a substrate S′ bearing on a surface thereof a UV photosensitive film S₁ consisting of (i) a UV induced index pattern P₁ and (ii) parts P₂ that are not UV induced, wherein the index pattern P₁ has a refractive index n₁ at the wavelength of the illumination radiation, the non-UV induced parts P₂ has a refractive index n₀ at the wavelength of the illumination radiation, with n₁≠n₀, and n₀ and n₁ remain substantially unchanged when the mask is exposed to the illumination radiation during the lithographic process.

In a preferred embodiment, in the mask of the present invention, n₁−n₀>1×10⁻⁴. In another preferred embodiment, in the mask of the present invention, the index pattern P₁ has a thickness d chosen to create a near 180° phase shift of the illumination radiation used in the lithographic process, with respect to the non-UV induced parts P₂. The edge of the index pattern may have a tapering gradient in terms of amount of phase shift. The edge of the index pattern may have a refractive index gradient. In still another preferred embodiment, the index pattern has an arbitrary dimension in terms of thickness, width and length as well as an arbitrary distribution of refractive index change varying in a certain range. In one embodiment, the index pattern is a grating having a pitch of less than 300 nm. In one embodiment, above the surface of the film S₁ of the mask of the present invention, there exist additional feature patterns P₃ formed by materials opaque or attenuating to the illumination radiation used in the lithographic process. Such opaque material may be, for example, Cr or modified Cr. And the attenuating material may create 180° phase shift with respect to the ambient atmosphere in which the mask is placed during the lithographic process.

In a preferred embodiment, in the mask of the present invention, the film S₁ is formed by a UV photosensitive boro-germano-silicate glass having a composition consisting essentially, expressed in terms of weight percentage, of: 0-20% of B₂O₃, 5-25% of GeO₂ and the remainder SiO₂. Preferably, the glass has a composition consisting essentially, expressed in terms of weight percentage, of: 0-10% of B₂O₃, 10-18% of GeO₂ and the remainder SiO₂. More preferably, the glass has a composition consisting essentially, expressed in terms of weight percentage on an oxide basis, of: 5-10% of B₂O₃, 10-18% of GeO₂ and the remainder SiO₂. Preferably, the glass is further loaded with H₂ molecules at a level of at least 10¹⁸ molecules/cm³. Optionally, the glass has a Ge oxygen deficiency center (GeODC) level of at least 100 dB/mm at 240 nm. Preferably, the index patter P₁ is substantially free of stress and birefringence. Preferably, the film S₁ has a substantially flat and smooth surface.

A second aspect of the present invention is a process for making a mask having a pattern P₀ transferable onto an image-receiving substrate when subjected to illumination radiation in a lithographic process, comprising the following steps:

(a) providing a substrate S′ transparent to the lithographic wavelength of the lithographic process in which the mask is used;

(b) depositing on a surface of S′ a UV photosensitive film S₀ having a refractive index n₀ at the wavelength of the illumination radiation to which the mask is subjected to during the lithographic process, said film S₀ having a lower surface bonding to the substrate S′, and an upper surface opposite to the first surface;

(c) selectively exposing part of the film S₀ to UV radiation of less than 280 nm with an effective fluence for an effective amount of time, whereby producing a film S₁ consisting of (i) a UV induced index pattern P₁ having a refractive index n₁, with n₀≠n₁, and (ii) parts P₂ that are not UV induced having a refractive index n₀; and

(d) optionally, forming additional pattern features P₃ above the upper surface of the film S₀ or S₁ by depositing films of materials opaque or attenuating to the illumination radiation.

In a preferred embodiment of the process of the present invention, in step (c), the fluence and wavelength of the UV radiation used to pattern the film S₀, as well as the exposure time are chosen such that the thickness d and refractive index n₁ of the index pattern P₁ meet the following requirement:

d·(n₁−n₀)≈λ/2 (4)

where λ is the wavelength of the illumination radiation used in the lithographic process, thereby the pattern P₁ creates a near 180° phase shift of the illumination radiation with respect to the non-UV induced parts P₂.

In one embodiment of the process of the present invention, in step (c), the fluence and wavelength of the UV radiation used to pattern the film S₀, as well as the exposure time are chosen such that the index pattern P₁ has a tapering edge in terms of amount of phase shift. The fluence of the UV radiation for patterning the film S₀ may be adjusted by tuning the fluence of the radiation source or by using gradient attenuating mask. In one embodiment, a contact phase mask is used in patterning the film S₀.

Preferably, in step (b) of the process of the present invention, after the photosensitive film S₀ is deposited on the substrate S′, it is subjected to an annealing step in the presence of, for example, N₂, inert gases or air. Preferably, in the UV writing step (c), the induced index pattern P₁ is substantially free of stress and birefringence. Preferably, the formation of the induced index pattern substantially does not involve compaction or density change of the film S₀, and the surface of the film S₁ having the induced index pattern P₁ is substantially flat and smooth. Annealing of the film upon deposition is conducive to the elimination or reduction of compaction during the UV writing step (c).

In an embodiment of the process of the present invention, in step (d), additional features are formed above the upper surface of the film S₁ or S₀. Step (d) may be carried out before or after step (c). The formation of additional features in step (d) may be carried out by using conventional methods, including photoresist deposition, exposure, development, selective etching of the deposited material, resist stripping, etc. Additional attenuating phase-shift features may be created as part of features P₃.

In a preferred embodiment of the process of the present invention, the photosensitive film S₀ in step (b) is formed by a UV photosensitive boro-germano-silicate glass having a composition consisting essentially, expressed in terms of weight percentage, of: 0-20% of B₂O₃, 5-25% of GeO₂ and the remainder SiO₂. Preferably, the glass has a composition consisting essentially, expressed in terms of weight percentage, of: 0-10% of B₂O₃, 10-18% of GeO₂ and the remainder SiO₂. More preferably, the glass has a composition consisting essentially, expressed in terms of weight percentage on an oxide basis, of: 5-10% of B₂O₃, 10-18% of GeO₂ and the remainder SiO₂. Optionally, the glass is further loaded with H₂ molecules at a level of at least 10¹⁸ molecules/cm³. Preferably, the glass has a Ge oxygen deficient center (GeODC) level of at least 100 dB/mm at 240 nm.

A third aspect of the present invention is a photosensitive boro-germano-silicate film with a refractive index n₀, which, upon being exposed to UV radiation less than 280 nm at an effective fluence for a sufficient amount of time, such as with a fluence of about 50 mJ/cm² for about 60 minutes, has a refractive index n₁, with n₁≠n₀, said glass having a Ge oxygen deficient center (GeODC) level of at least 100 dB/mm at 240 nm and a composition consisting essentially, expressed in terms of weight percentage, of: 0-20% of B₂O₃, 5-25% of GeO₂ and the remainder SiO₂. Preferably, the film has a composition consisting essentially, expressed in terms of weight percentage, of: 0-10% of B₂O₃, 10-18% of GeO₂ and the remainder SiO₂. More preferably, the film has a composition consisting essentially, expressed in terms of weight percentage on an oxide basis, of: 5-10% of B₂O₃, 10-18% of GeO₂ and the remainder SiO₂. Optionally, the film is further loaded with H₂ molecules at a level of at least 10¹⁸ molecules/cm³. Preferably, after being exposed to 248 nm at a fluence of 50 mJ/cm² for 60 minutes, the film has an induced refractive index change Δn=n₁−n₀>1.0×10⁻⁴, more preferably Δn>1.0×10⁻³ under such condition.

A fourth aspect of the present invention is a plasma enhanced chemical vapor deposition (PECVD) process for making the photosensitive B₂O₃—GeO₂—SiO₂ film of the present invention. Said process involves using tetramethoxygermane as the germanium source. In a preferred embodiment, the process involves using tetraethoxysilane and trimethylboron as the silicon and the boron source, respectively. Preferably, the film is annealed, for example, in helium, argon, air or N₂ after being deposited.

The final aspect of the present invention is a mask blank comprising a flat substrate S′ bearing a UV photosensitive film S₀ on a surface thereof, wherein

(I) the film S₀ has a refractive index n₀ at the wavelength of the radiation used in a lithographic process;

(II) upon selective exposure to UV radiation less than 280 nm at an effective fluence for an effective amount of time, an index pattern P₁ transferable to an image-receiving substrate when subjected to illumination radiation in a lithographic process can be formed within the film S₀, said index pattern P₁ having an integrated refractive index n₁, with n₁≠n₀; and

(III) n₀ and n₁ remain substantially the same when exposed to the illumination radiation used in the lithographic process.

The mask blank of the present invention may further bear above the upper surface of the film S₀ a film opaque or attenuating to the illumination radiation used in the lithographic process. In a preferred embodiment of the mask blank of the present invention, above the upper surface of the film S₀, an additional layer of Cr and/or modified Cr is formed. Advantageously, the film S₀ of the mask blank of the present invention is formed by a UV photosensitive boro-germano-silicate glass having a composition consisting essentially, expressed in terms of weight percentage, of: 0-20% of B₂O₃, 5-25% of GeO₂ and the remainder SiO₂. Preferably, the film has a composition consisting essentially, expressed in terms of weight percentage, of: 0-10% of B₂O₃, 10-18% of GeO₂ and the remainder SiO₂. More preferably, the glass has a composition consisting essentially, expressed in terms of weight percentage on an oxide basis, of: 5-10% of B₂O₃, 10-18% of GeO₂ and the remainder SiO₂. Optionally, the glass is further loaded with H₂ molecules at a level of at least 10¹⁸ molecules/cm³. Preferably, the film S₀ of the photomask blank of the present invention, when subjected to UV exposure to create the induced index pattern P₁ within it, substantially does not involve a compaction. Preferably, when the induced index pattern P₁ within the film S₀ is produced via UV exposure, it is substantially free of stress and birefringence.

The mask and method of the present invention can overcome the drawbacks of conventional phase-shifting masks in terms of cost, turnaround time and inspectability and repair.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification.

### BRIEF DESCRIPTION OF THE DRAWINGS

In the accompanying drawings,

FIG. 1 is a schematic illustration of the operating principle of a traditional binary mask and a simple alternating aperture phase-shifting mask.

FIGS. 2A, 2B and 2C are schematic illustration of the plan, side elevation (along line A) and end elevation (along line B) views, respectively, of an alternating aperture phase-shifting mask.

FIG. 3A is a schematic illustration of the operating principle of an attenuating phase-shifting mask.

FIG. 3B is a schematic illustration of the manufacture steps of an attenuating phase-shifting mask, using TiSiN as the attenuating phase-shifting material.

FIG. 4 is a schematic illustration of chromeless phase-shifting mask and alternating aperture phase-shifting mask in use.

FIGS. 5A, 5B, 5C and 5D are schematic illustration of the cross-sections of the index pattern designs of exemplary masks of the present invention.

FIGS. 6A, 6B and 6C are schematic illustration of the cross-section of chromeless phase-shifting masks in the prior art as compared to the mask of the present invention illustrated in FIGS. 5A, 5B and 5C, respectively.

FIGS. 7A and 7B are schematic illustration of the cross-section of the pattern designs of exemplary masks of the present invention having additional features on top of the photosensitive film surface.

FIG. 8 is a schematic illustration of the cross-section of an alternating phase-shifting mask known in the prior art.

FIGS. 9 and 10 are diagrams showing the absorption spectrums of an exemplary B₂O₃—GeO₂—SiO₂ ternary film of the present invention, indicating the presence of GeODC.

FIG. 11 is a diagram showing the absorption spectrums of the same exemplary film as shown in FIGS. 9 and 10, not hydrogen loaded, after exposure to 248-nm radiation.

FIG. 12 is a diagram showing the absorption spectrums of the same exemplary film as shown in FIGS. 9 and 10, hydrogen loaded, after exposure to 248-nm radiation.

FIGS. 13 and 14 are diagrams showing the absorption spectrums of a B₂O₃—GeO₂—P₂O₅—SiO₂ quarterary film, indicating very small amount or no presence of GeODC.

FIG. 15 is a diagram showing the absorption spectrum of a GeO₂—SiO₂ binary film deposited in accordance with the process of the present invention, indicating the presence of GeODC.

FIGS. 16 and 17 are diagrams showing the absorption spectrum of two GeO₂—SiO₂ binary films not deposited according to the process of the present invention, indicating very small amount of GeODC.

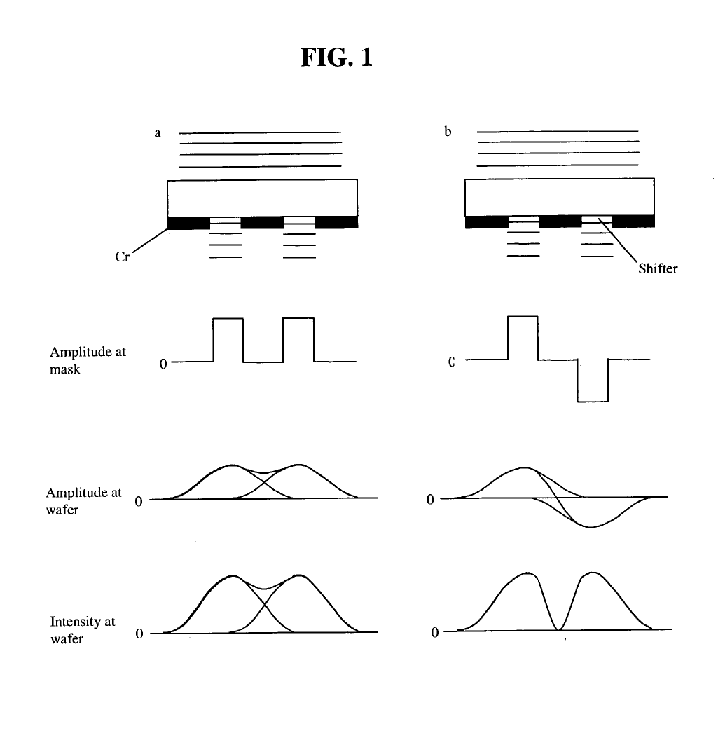

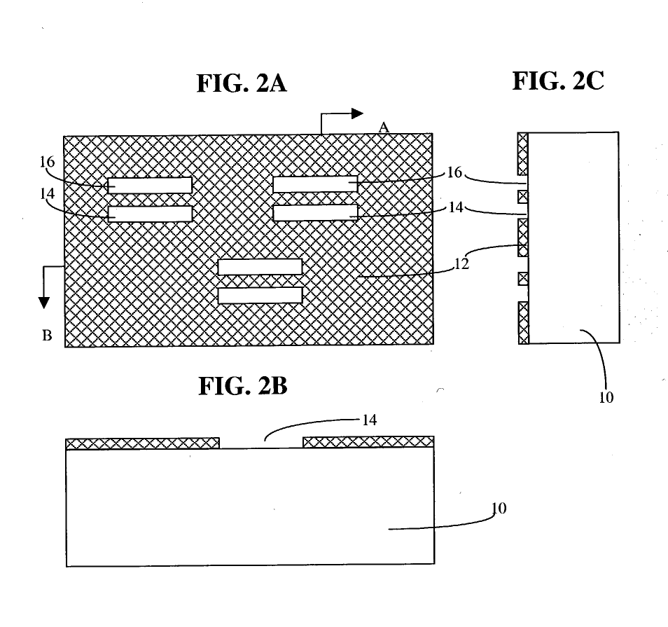

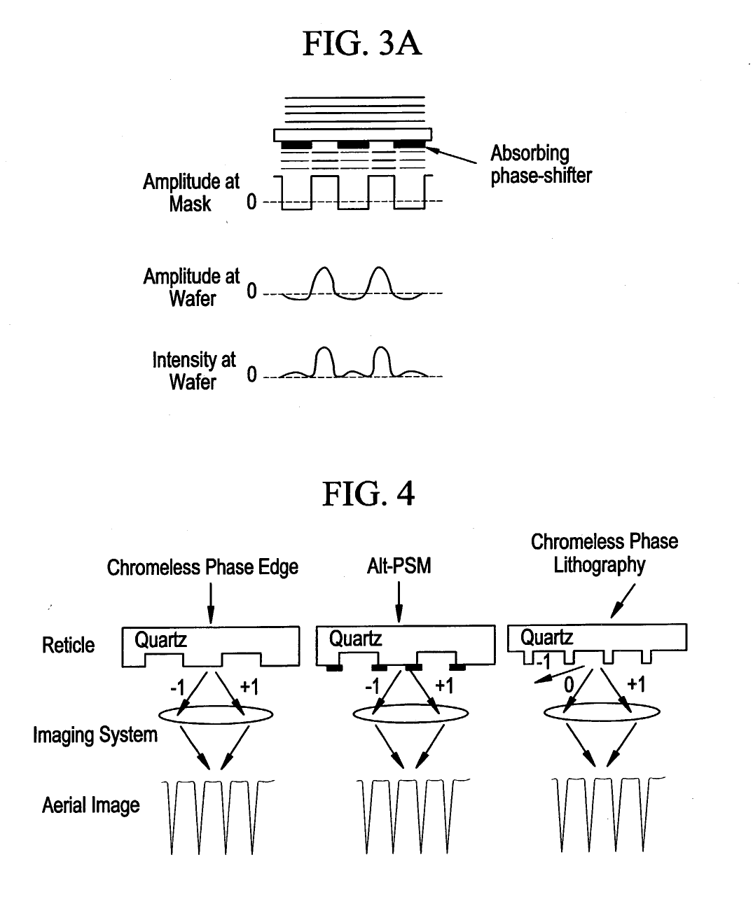

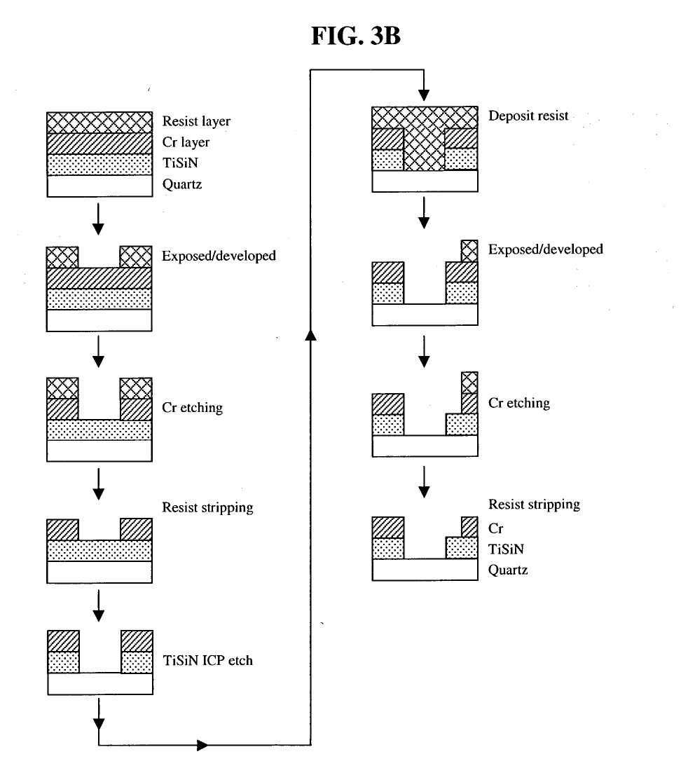

### DETAILED DESCRIPTION OF THE INVENTION

The literature concerned with the UV-photosensitive based fiber Bragg gratings in Ge-doped silica optical fibers is extensive. Although there is still some uncertainty and disagreement, it is generally regarded that there are two distinct mechanism responsible for the UV-laser induced refractive index change in this glass system. The first observed effect has as its origin in an oxygen deficient center (ODC) that has a characteristic absorption band at 240 nm. The defect is created during the fabrication process. For example, in the flame hydrolysis deposition process, the defect concentration can be directly related to the oxygen partial pressure during the consolidation step. This absorption associated with the GeODC is bleached by UV-light and is thought to lead to the refractive index change through a Kramers-Kronig effect. Schematically one can write the photoreaction in the following way:

$$[ \frac{O —Ge—Ge—O}{{—O—Ge}^{+ 2}} ] + ℏ ω ⇒ {—Ge}^{′} + {—Ge}^{+} + e \qquad ( 5 )$$

Here, the oxygen deficient center written in brackets are the two representations of the conjectured center. The GeE′ (analogous in structure to the SiE′ center) is readily observed by ESR and UV-spectroscopy after exposure. In general, there is a good correlation between the amount of GeE′ produced and the induced refractive index change.

The concentration of the defect center is controlled largely by the method of deposition, primarily through the redox conditions. For example, in the IV process which is essentially a closed system, the ambient can be controlled to be reducing in nature, and thus can be efficient in producing the GeODC. In contrast, the GeODC concentration in the OV process is controlled by the subsequent consolidation ambient. One is limited to how reducing this can be due to the possible loss of germania. To make matters even more complicated, there are two bleaching behaviors of the defect. It is possible to have a strong GeODC absorption, but it is stable and difficult to bleach. This is typically the case in fibers when the deposition is by OVD. On the other hand, IV deposition produces a very strong and bleachable effect.

The more recently reported photorefractive effect requires the presence of a high concentration of dissolved molecular hydrogen in the glass. The hydrogen mediates a photoreaction that leads to a large induced absorption through SiOH (GeOH) formation as schematically indicated below:

—Si—O—Ge—+H₂+-hω [symbol] SiOH+GeH (6)

The induced index change correlates well with the amount of OH production as well as the strong induced absorption in the vacuum ultraviolet portion of the spectrum. It has been shown that the H₂-mediated effect does not require the oxygen deficient defect, although the presence of the defect can enhance the rate at which the refractive index develops with exposure.

In optical fibers where the bulk of the results have been obtained, it has been found that although the GeODC is not required, if it is present in the molecular hydrogen mediated effect, the induced index effect proceeds at a much faster rate. It appears that the GeODC itself can react with hydrogen in the presence of UV light. U.S. Pat. No. 5,896,484 to Borrelli et al. discusses this effect.

As an aspect of the present invention, the present inventors have developed a highly effective plasma enhanced chemical vapor deposition (PECVD) process for depositing GeO₂—SiO₂ binary or GeO₂—SiO₂—B₂O₃ ternary film on planar substrates. The PECVD process of the present invention utilizes tetramethoxygermane (Ge(OCH₃)₄) as the Ge source. Tetraethoxysilane (Si(OCH₂CH₃)₄) and trimethylboron (B(CH₃)₃) can be used as the silicon and the boron source, respectively. Optionally, oxygen, N₂O or O₃ is used as oxidizers in the PECVD process. As in typical CVD processes, inert diluting gases may be used in the deposition process. The process maximizes the concentration of the bleachable GeODC defect to a level of at least 100 dB/mm at 240 nm and thus optimizes the ensuing photosensitivity. The resulted film, as deposited and after annealing at 800-1100° C. in helium, air and oxygen, exhibits unusually large concentration of bleachable GeODC. As a consequence the value of UV induced refractive index change can be made sufficiently large to obviate the need for hydrogen loading. The film, which constitutes another aspect of the present invention, has a composition consisting essentially, expressed in terms of weight percentage, of: 0-20% of B₂O₃, 5-25% of GeO₂ and the remainder SiO₂. Preferably, the film has a composition consisting essentially, expressed in terms of weight percentage, of: 0-10% of B₂O₃, 10-18% of GeO₂ and the remainder SiO₂. More preferably, the glass has a composition consisting essentially, expressed in terms of weight percentage on an oxide basis, of: 5-10% of B₂O₃, 10-18% of GeO₂ and the remainder SiO₂. Preferably, the film as a GeODC concentration of at least 100 dB/mm at 240 nm, more preferably at least 300 dB/mm at 240 nm. The film may be further loaded with H₂ molecules at a level of at least 10¹⁸ molecules/cm³. In contrast to the film of the present invention, film deposited by a PECVD process using typical silicon and germanium sources, SiH₄ and GeH₄ respectively, exhibited almost no GeODC. GeO₂—SiO₂ film known in the prior art usually has a GeODC level of 100 times lower than that of the film of the present invention.

Photosensitive materials have been widely used in fiber Bragg gratings. The present inventors realized that the photosensitivity of these materials render them proper as a mask media for recording patterns in lithographic applications. By using UV radiation with a proper fluence and dosage, permanent index patterns may be created within the body of a photosensitive substrate. Such index patterns, when illuminated by the radiation in a lithographic process, can transfer image information onto an image-receiving substrate, such as a wafer. Such photosensitive material is particularly advantageous for phase-shifting masks.

In broad terms, the unconventional process of the present invention for creating a mask having a pattern P₀ transferable onto a image-receiving substrate comprises the following steps:

(a) providing a substrate S′ transparent to the lithographic wavelength of the lithographic process in which the mask is used;

(b) depositing on a surface of S′ a UV photosensitive film S₀ having a refractive index n₀ at the wavelength of the illumination radiation to which the mask is subjected to during the lithographic process, said film S₀ having a lower surface bonding to the substrate S′, and an upper surface opposite to the first surface;

(c) selectively exposing part of the film S₀ to UV radiation of less than 280 nm with an effective fluence for an effective amount of time, whereby producing a film S₁ consisting of (i) a UV induced index pattern P₁ having a refractive index n₁, with n₀≠n₁, and (ii) parts P₂ that are not UV induced having a refractive index n₀; and

(d) optionally, forming additional pattern features above the upper surface of the film S₀ or S₁ by depositing films of materials opaque or attenuating to the illumination radiation.

Obviously, step (b) is always performed before steps (c) and (d). It is to be noted that, if step (d) is involved in the process of the present invention, step (c) may be carried out before step (d), in which case pattern P₁ is formed first on the film S₀ of the mask blank, and pattern P₃ is formed afterwards. Alternatively, step (d) may be implemented before step (c), which means that features P₃ is formed first above the upper surface of film S₀, and the film S₀ bearing above its surface the pattern P₃ is subsequently exposed to patterning UV light, whereby pattern P₁ is formed. Either way, the patterns P₁ and P₃ combine to form the overall pattern P₀ of the mask. Of course, in certain cases, pattern P₃ may be dispensed with and the index P₁ will constitute the whole pattern P₀ of the mask. In these cases step (d) is not carried out.

The steps of the process are discussed in detail as follows. Other aspects of the present invention, including the mask, the mask blank, the photosensitive film, and the process for making the film, of the present invention, are illustrated and can be understood by reference to the following description of the process of making the mask.

In step (a), the transparent substrate S′ can be made of any material used for manufacturing conventional masks. The bottom line is the substrate S′ should be transparent to the lithographic wavelength of the lithographic process. Preferably, at the lithographic wavelength of the lithographic process, the substrate should have a transmission of at least 70%, more preferably at least 75%, most preferably at least 80%. In traditional photomasks, the standard substrate material was soda lime glass. Later, white crown was introduced to reduce defects. And still later, borosilicate glass was introduced to reduce temperature effects on the mask. Currently, as the lithographic wavelength has gone shorter, fused silica has been introduced for further temperature effects and to give better transmission. For the purpose of example and illustration only, the substrate S′ in the present invention process can be made of borosilicate glass, fused silica, doped fused silica, low thermal expansion optical glass-ceramic materials, etc. For masks used in 248-nm and shorter wavelength photolithography, the substrate is advantageously made of fused silica or doped fused silica. Advantageously, the surfaces of the substrates S′ have a flatness that meets the requirement of optical distortion in mask manufacture. However, where necessary, the surface of substrate S′ may be engineered to any specific topography before the deposition of the photosensitive film in step (b) by using methods known in the art, such as dry etching and wet etching. Preferably, the thickness of the substrate S′ is sufficient to satisfy the requirement for gravitation sag and pattern placement accuracy. Preferably, the substrate S′ has a chemical durability that can withstand the mask producing environment, such as wet etching and dry etching.

Step (b) of the present invention mask-making process involves deposition of a photosensitive film on a surface of the substrate S′. Preferably, the photosensitive film is the boro-germano-silicate film described supra. The film may be loaded with hydrogen or not. The present inventive PECVD process for forming the boro-germano-silicate film, described supra, can be advantageously employed in forming the film S₁, though other deposition method is not excluded as long as they can meet the requirements for the film S₀. Similar to the substrate in many conventional masks, the photosensitive film S₀ preferably has a flat upper surface that meet the requirements of optical distortion in the lithographic processes in which the mask is used. For example, the surface of the film S₀ may be polished to a flatness of 1 to 2 μm peak to valley, or even a higher flatness where necessary. If the present inventive PECVD process is used, typically the roughness of surface of the film as deposited on the substrate S′ can reach as low as 2% of the film thickness. Where the process is optimized and tightly controlled, roughness of as low as 1% of the thickness can be obtained. Of course, where necessary, the surface of the film S₀ may be engineered to have any specific topography prior to step (c) or (d) by using methods available in the prior art, such as dry etching and wet etching. The film S₀ preferably has a homogeneous composition and a substantially uniform refractive index n₀. The film S₀ should be transmissive to the illumination radiation used in the lithographic process. Preferably, at the lithographic wavelength of the lithographic process, the substrate should have a transmission of at least 70%, more preferably at least 75%, most preferably at least 80%.

The thickness of the film S₀ formed on the substrate S′ can be easily controlled if the PECVD process of the present invention is used. Conventional approaches in CVD for controlling the deposition thickness can be used for that purpose. Advantageously, the film S₀ has a thickness identical to the thickness d of the index pattern P₁ to be written into the film, viz., the index pattern P₁ extends through the whole thickness of the film S₀. The advantages of having this thickness will be discussed in more detail, infra.

The film S₀ deposited onto the substrate S′ is preferably subjected to annealing upon deposition. Annealing can be carried out at an elevated temperature, such as 800-1100° C., for a period of 1-2 hours in the presence of N₂, inert gases or air. Such annealing step can densify the deposited film and reduce or eliminate compaction in the subsequent UV writing step.

It is preferred that the boro-germano-silicate film for the masks of the present invention has a composition that has a fundamental absorption not over 300-nm, preferably not over 248-nm (5-eV). The fundamental absorption edge of pure silica, for example, is determined by the transition from the band consisting of the overlapping 2 p oxygen orbitals (valence band) to the band made up from the sp³ non-bonding orbitals of silicon (conduction band). It is believed that, however, the addition of the network substitution ions such as boron, aluminum, and germanium to silica has much less influence on the absorption edge. A high transparency of the film of the deep UV light, such as 248-nm radiation, is preferred for the glass. Impurities such as transition metal ions or heavy metal ions that are inadvertently incorporated into the film during the deposition process, must be kept to the <1 ppm level. These ions, even in small amounts have a dramatic adverse effect on the UV-absorption edge. If the PECVD process of the present invention using Ge(OCH₃)₄, Si(OCH₂CH₃)₄ and B(CH₃)₃ as the source of germanium, silicon and boron, described supra, is employed, a high purity film without contamination can be easily obtained. Also, the PECVD process of the present invention can produce a film with little stress, which is beneficial to the mechanical and optical properties of the film.

Preferably, the film S₀ has a chemical durability that can withstand the chemical environment of the process of forming the mask of the present invention, such as the dry etching and/or wet etching steps where necessary. In this case, the additional features P₃ above the film S₁ can be formed directly on the upper surface of S₁. In case the photosensitive layer S₀/S₁ is not robust enough to withstand the environment, it is contemplated that a very thin protective layer resistant to the environment, such as a silica layer, may be formed on the upper surface of the film S₀/S₁, and the additional features P₃ are formed on the surface of the protective layer. Of course, the protective layer should be transmissive to the lithographic radiation, as is required for the substrate S′. As long as the thickness of the protective layer can prevent undesired etch of the film S₀/S₁, the thinner the protective layer is, the better. In addition, the protective layer should preferably have an even thickness and a low surface roughness in order not to create optical distortion.

The substrate S′ bearing film S₀ may be prepared to meet the requirements described supra, among others, then sold and used as mask blanks of the present invention. Alternatively, the film S₀ may be subject to part of step (d) in the process of the present invention, for example, deposition of a film opaque or attenuating above a surface thereof, and then sold or used as a mask blank. For example and for the purpose of illustration only, a Cr layer and/or modified Cr layer used on conventional photomasks can be deposited on film S₀. As mentioned above, an intermediate protective layer, such as a silica layer, may be formed between the film S₀ and the additional opaque and/or attenuating layer, as long as it meets the requirements described above, where the film S₀ and/or S₁ cannot resist the photomask forming environment. The resulting product may then be sold and used as photosensitive chrome mask blank, a type of the mask blank of the present invention. Usage of this type of mask will be described and illustrated infra. The deposition of such additional opaque or attenuating film can be effected using methods known in the art, such as sputtering, ion plating, and the like. The film may be further modified to obtain a differing etching rate, reflectivity, etc. For example, where the additional opaque layer is Cr, it may be modified in accordance with U.S. Pat. Nos. 4,530,891 and 4,463,407, the relevant portion of which are incorporated herein by reference.

Where the mask blank bears film S₀ without additional opaque or attenuating surface layer, step (c) can be implemented before step (d), if the optional step (d) is to be taken at all. Needless to say, when the mask blank is a film S₀ covered by an additional layer of Cr above a surface thereof, step (d) need be carried out first in order to expose the upper surface of film S₀ before its patterning in step (c) can be implemented. This is because, it is preferred that the patterning radiation in step (b) is applied directly to the upper surface on which the additional features P₃ are created in step (d). It is also contemplated that steps (c) and (d) may be carried out in various order for multiple times in order to create the desired final pattern.

Step (d) is carried out using conventional means available in the art. For example, where the additional features are chrome features, they can be formed by deposition of chrome layer where necessary (such as where step (d) is undertaken after step (c)), preferably by sputtering, coating of a resist, exposure of the resist to patterning radiation, development of the resist, etching the chrome layer, etc.

In step (c), the upper surface of the film S₀ is selectively exposed to UV writing light to create the pattern P₁. As mentioned supra, where step (d) is first carried out and additional features have been formed above a surface of film S₀, the patterning light in step (c) is directed to the exposed area of the upper surface of the film S₀.

The UV writing light has a wavelength capable of inducing refractive index change within film S₀. For the masks of the present invention, the writing light has a wavelength less than 280 nm. Preferably, the light source is a coherent laser source. For the boro-germano-silicate photosensitive films, the writing light can be advantageously 248-nm deep UV KrF excimer laser. It is noted that a tunable Nd/YAG laser which emits radiation at 268 nm and 270 nm could be used in place of the KrF excimer laser. Preferably, the light source provides a uniform intensity across the cross-section so that even writing can be obtained. In order to write patterns into the film S₀, sufficient radiation fluence and exposure time are required. It is found that for the photosensitive materials, the induced refractive index change (Δn) is a function of both radiation fluence and exposure time. However, in a thin film above a certain limit of exposure fluence and exposure time, the induced refractive index change Δn tends to saturate and remain constant. Typically, for the boro-germano-silicate photosensitive glasses, in order to induce a meaningful index change at 248 nm, a fluence of at least 10 mJ/cm² is desired. Preferably, the patterning UV light has a fluence of at least 20 mJ/cm², more preferably at least 30 mJ/cm², most preferably at least 40 mJ/cm². Typically, until the induced refractive index Δn is saturated within the film, at a lower fluence, to induce a given amount of index change for a given effective thickness of index pattern, more exposure time is required. The photosensitive film S₀ does not undergo a UV reduced refractive index change when exposed to the radiation of the lithographic process in which the mask is to be used. This is because the fluence of the lithographic illumination is very low, usually in the order of micro joules/cm², which is insufficient to induce the index change in the film.

Selective writing or patterning can be effected in various approaches. For example, one preferred approach involves using vector or raster scanning. The system for exposing resist in the manufacture of conventional mask can be adapted for use in the present invention for patterning the film S₀. Specifically, the desired pattern to be written into film S₀ is defined by an electronic data file loaded into a programmed exposure system which scans the writing laser beam in a raster or vector fashion across the exposed surface of film S₀. One such example of a raster scan exposure system is described in U.S. Pat. No. 3,900,737 to Collier. As the laser beam is scanned across the surface, the exposure system directs the beam at addressable locations on the surface as defined by the electronic data file. The laser beam may have fixed fluence, or it may further be equipped with a fluence modulator, which is programmed to adjust the fluence where necessary at given locations on the surface. Scanning speed may be varied to adjust the exposure time. As a result, index patterns having various dimensions can be created within the film S₀. In this approach, no resist or additional layers are required above the upper surface of film S₀. However, complex patterns having various shapes, width and length can be created. Another approach involves using photoresist. In this approach, similar to the manufacture of a conventional mask, a layer of resist is coated onto the upper surface of film S₀. Subsequently, the resist is exposed with patterns using well-known exposure systems described above. The resist layer is then developed to reveal only the portions of the surface of film S₀ to be patterned. With the remaining resist on, the film S₀ is then exposed to the patterning UV laser beam. After the pattern is created within the film S₀, the remaining resist is stripped off. In this approach, electronic beam (E-beam) exposure system and corresponding resists can be used, and fine and precision patterns can be created. In a third approach, a contact or phase mask may be used when exposing the film S₀ to the patterning light, thus eliminating the need of a complex scanning system. This approach is especially suitable for creating simple gratings.

The inventors have found that before the induced refractive index change is saturated in the film S₀, the induced refractive index change (Δn) along the depth or thickness of the index pattern P₁ is not always identical. For an unsaturated thick film having a high thickness, for example, 3 mm to 6 mm, the index pattern tends to have an effective pattern depth or thickness d less than the substrate thickness. Along the effective thickness d, there is an index gradient. Typically, the area adjacent to the upper surface of S₀ to which the exposure light is directly applied has the highest refractive index change, and the lowest portion of index pattern has the same index as film S₀. Without intending to be bound by any particular theory, the inventors believe this is because the patterned glass is not subjected to the same radiation fluence along the pattern depth because of light absorption along the light path. Therefore, in the context of and for the purpose of the present application, the refractive index n₁ of the induced index pattern P₁ is an integrated index along the effective thickness d of the index pattern. Assume at a given thickness t (0≦t≦d) measured from the surface of the substrate, the refractive index of pattern P₁ is a substantially uniform number n(t), then the total phase shift (s) caused by the index pattern P₁ along the whole effective thickness d can be expressed as follows:

$$s = 2 π \frac{{\int }_{0}^{d} ( n ( t ) - {n}_{0} ) ) ⅆ t}{λ} = \frac{2 π ( {n}_{1} - {n}_{0} ) \cdot d}{λ} \qquad ( 7 )$$

Thus, the integrated refractive index n₁ is

$${n}_{1} = {n}_{0} + \frac{1}{d} {\int }_{0}^{d} ( n ( t ) - {n}_{0} ) ) ⅆ t \qquad ( 8 )$$

A great advantage of the process of the present invention in creating mask is, by carefully adjusting radiation fluence and exposure time, both effective thickness d of the index pattern and the refractive index change Δn=(n₂−n₁) can be adjusted. Thus a gray-scale mask with an index pattern having arbitrary distribution of d and Δn can be produced. Through the entire effective thickness d of the index pattern, phase shift s=2π·d·Δn/λ of the radiation illumination from 0 to kπ (where k is a positive integer) can be obtained. Of particular interest is s≈π, where the mask is a near 180° phase-shifting mask. Ideally, s=π. However, practically, it is difficult, it not impossible, to always obtain a strict 180° phase shift. Thus, in the context of the present application, a 180° phase shift or a near 180° phase shift is meant to be within the range 180±5°, more preferably within the range 180±2°. For certain area of the mask, where any arbitrary phase shift amount is desired, d and Δn can be adjusted by tuning the radiation fluence and changing exposure time to reach the goal.

However, as mentioned supra, it is advantageous to deposit a thin film having the effective thickness d of the index pattern P₁ to be written into the film. The primary pattern area of the film should be advantageously written by an exposure fluence and time over the saturation limit. As a result, at the thickness t (0≦t≦d) measured from the upper surface along the thickness d of the film, also the thickness of the index pattern P₁, the index pattern P₁ has a uniform refractive index n₁. Therefore, as can be seen from equation (7), the amount of phase shift can thus be controlled by varying the thickness d of the film S₀. For example, in a saturated pattern P₁ having an induced refracted index change Δn=2×10⁻³, the film thickness d required for a 180° phase shift is 62 μm at 248-nm, and 41.5 μm at 193-nm. And where Δn=3×10⁻³, the film thickness required for a 180° phase shift is 41.5 μm and 32 μm at 248-nm and 193-nm, respectively. Δn of this order can be induced in the boro-germano-silicate film of the present invention. In the PECVD process of the present invention, the film thickness can be easily adjusted using technology known in the art, and boro-germano-silicate film of the present invention having these thicknesses can be created.

Even in a thin film that can be easily saturated, it is sometimes desired not to have all exposed area saturated. This is particularly true with regard to the edge portion of the index pattern P₁. For reasons described infra, the edge portion may be desired to have a lower thickness or a lesser induced refractive index change compared to the primary index pattern area. Or, in certain situations, gray scale masks having an arbitrary distribution of thickness and induced refractive index change Δn may be desired.

Another advantage of the process for making the masks of the present invention lies in the ease of correction of defects. Defects in the index pattern uncovered in inspection can be easily corrected by using additional exposure. Alternatively, selective etching of the substrate of the defective area may be used to make the necessary correction as well.

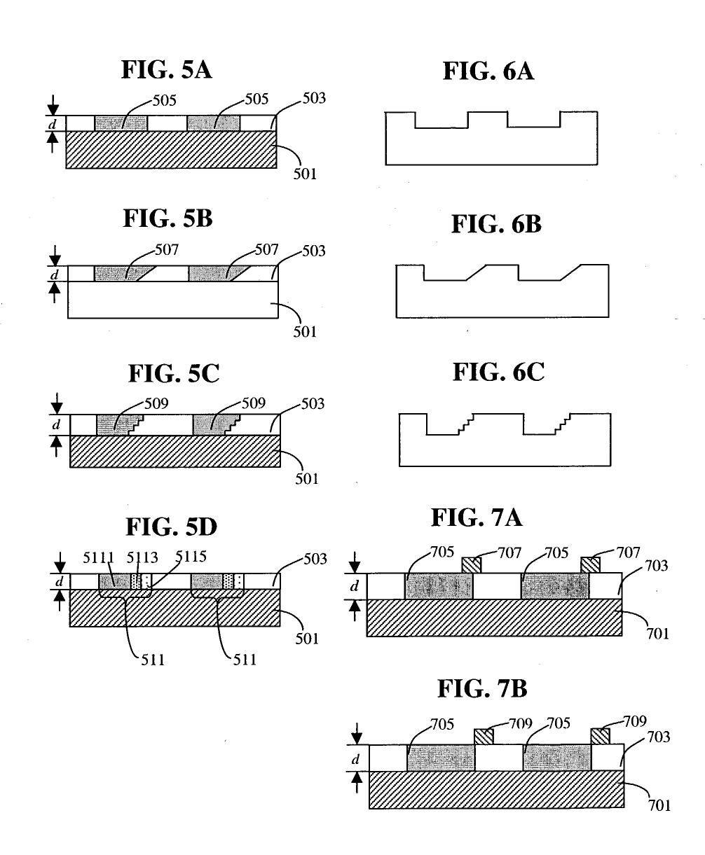

FIGS. 5A-5D illustrate schematically the cross-section of some simple phase-shifting mask designs of the present invention. Additional pattern features P₃ above the upper surface of the film, if any, are not shown. These embodiments involve a flat, transparent substrate 501 bearing a photosensitive thin film 503 on the top. The film 503 has a refractive index n₀ in non-phase-shifting area and a thickness d. Phase shift features P₁ 505, 507, 509 and 511 are created via selective exposure to UV writing radiation. The phase shift features P₁ have an effective depth of d. In FIG. 5A, the 180° shifting patterns 505 has steep edges and are saturated, viz., the whole pattern 505 has a substantially uniform refractive index n₁. In FIG. 5B, the 180° shifting pattern 507 has a continuously unsaturated tapering edge portion with a tapering thickness. However, the thickness of the primary area of the pattern 507 is saturated and has a substantially uniform refractive index n₁. In FIG. 5C, pattern 509 has a step-wise unsaturated tapering edge portion with a tapering thickness. However, the thickness of the primary area of the pattern 509 is saturated and has a substantially uniform refractive index n₁. In FIG. 5D, pattern 511 is comprised of several portions 5111, 5113 and 5115 having substantially the same effective thickness d, but each having a differing integrated refractive index n₁₁₁, n₁₁₃, and n₁₁₅, respectively, with n₁₁₁<n₁₁₃<n₁₁₅ and d·(n₁₁₁−n₀)≈λ/2. 5111 is saturated and has a substantially uniform refractive index n₁₁₁ along the thickness. Thus 5111 creates a near 180° phase shift, whereas 5113 and 5115 creates a gradient in terms of phase shift. The function of the tapering edges of patterns 507 of FIG. 5B and 509 in FIG. 5C is similar to portions 5113 and 5115 in FIG. 5D. These phase shift gradient features are sometimes desired in phase-shifting masks, because the sharp edges of pattern 505 in FIG. 5A may be printable to the image-receiving substrate, such as a wafer.

The phase shift features 505, 507, 509 and 511 can all be realized by modulated UV scan of the photosensitive film 503 with relative ease, with limited number of scanning steps, possibly in one scan operation. Of course, where necessary, gray-scale masks can be used in creating the sloping edges of 507 and stepwise edge of 509 and the phase shift gradient 511. Also, as mentioned above, the features may be created with the aid of photoresist as well. However, in any event, the creation of these photomasks are far simpler than the chromeless phase-shifting masks described in the prior art. FIG. 6A-6C illustrates schematically the chromeless phase-shifting masks similar in operating principle to the present inventive FIGS. 5A-5C masks. In creating the FIG. 6A mask starting from fused silica substrate, the following steps are required: deposition of Cr layer; deposition of resist; exposure and development of resist; selective etching of Cr; selective etching of silica; stripping of resist; stripping of Cr layer. This is far more complex and far more expensive than the creation of FIG. 5A feature. Even if pattern 505 in FIG. 5A are created with the aid of resist, the production of FIG. 5A mask is still much simpler in that it does not involve the metalization and silica etching steps. The production of FIG. 6B chromeless phase-shifting mask requires the use of a special material having gradient etching rate, in addition to the steps for the FIG. 6A mask. The small step-wise features of FIG. 6C requires multiple steps of photoresist deposition, exposure and development, as well as multiple steps of etching of Cr and silica, which are too complex to be feasible and practical.

FIGS. 7A and 7B illustrate schematically the cross-section of some of the embodiments of the mask of the present invention having additional features P₃ on top of the index pattern P₁. In FIG. 7A, chrome features 707 are added on top of the surface of the photosensitive film 703 having index pattern 705. 701 is a transparent substrate supporting the photosensitive film 703. Some of these chrome features may cover the edge of the phase-shifting index pattern features 705. Similar to conventional phase shifting design, this type of design in FIG. 7A has some advantages. This type of design should typically be formed by performing step (c) of the process of the present invention first on the photosensitive film S₀ 703 without pre-formed chrome layers to create the phase shifting features, followed by creating the chrome opaque features 707 in step (d). In FIG. 7B, chrome features 709 are formed adjacent to the edge of the phase shifting features 705 but without overlapping. Since this design does not require the phase shifting feature to extend under the surface features, it can be formed by forming either features 705 or 707 first. Thus this mask may be created by using a mask blank having pre-formed chrome layer. Likewise, the phase shifting features 705 may have an edge having a gradient in terms of phase shift amount where necessary. Such gradient may be created by varying thickness of the pattern, induced refractive index change Δn, or both. It is to be understood that, though the additional surface features P₃ are illustrated in these figures as chrome layer, or other opaque or attenuating layers, 180° phase shifting or not, may be employed in conjunction with the opaque chrome layer, to create complex surface pattern designs where necessary. These features, together with the phase shifting index patterns in the photosensitive film of the mask of the present invention, supplement and/or mutually correct each other to form a pattern transferable to the image-receiving substrate, such as a wafer.

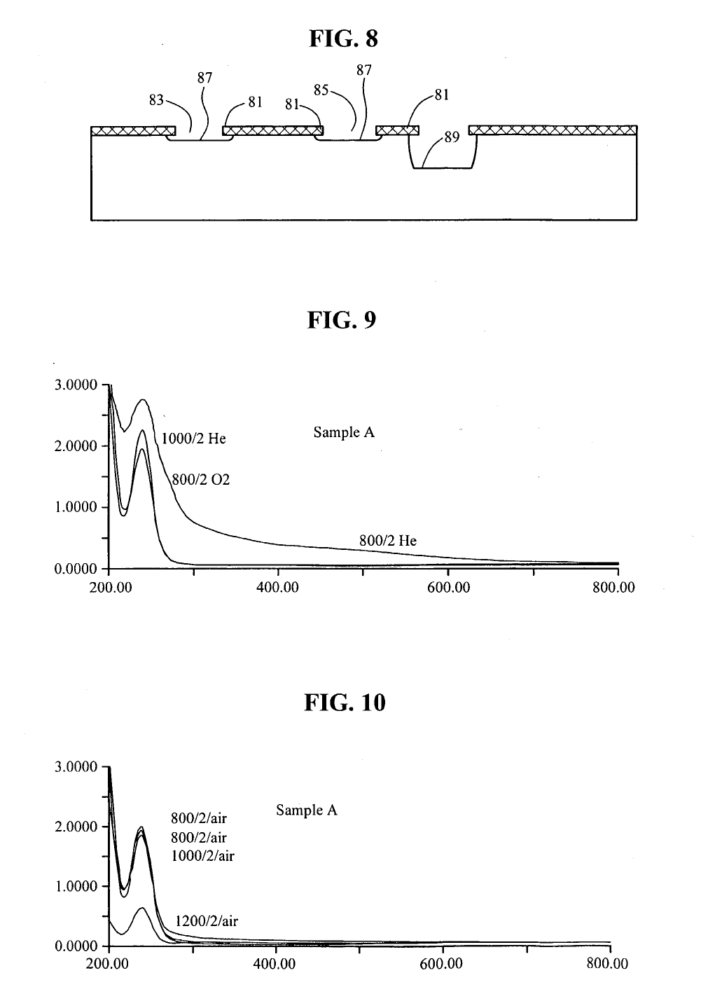

Again, the production of the FIGS. 7A and 7B masks is far simpler than the production of conventional phase-shifting masks operating under the similar principle. Also the produced masks have advantages over those of the prior art. FIG. 8 illustrates schematically the design of a conventional PSM corresponding to that of FIG. 7A. In FIG. 8, in order to ensure that the two types of aperture perform identically in an optical sense, except for the phase-shift, the substrate is etched back laterally under the opaque film, thus leaving the opaque film unsupported at the edge. The non-phase shifting apertures 803 and 805 and the phase shift apertures are noted. The trenches 807 and 809 etched in the substrate beneath the apertures are necessarily formed after the apertures are etched in the opaque layer, which is a high-cost process. The requirement to form a second custom pattern—by a process that can result in uncorrectable defects—significantly raises the cost of producing this type of conventional alternating aperture PSMs.

Various electronic design automation tools are known for preparing the patterns used in conventional and phase-shifting masks. In addition, OPC tools alter those patterns to account for the realities of the exposure systems. It is also known that the pattern of apertures on the phase-shifting mask need not correspond closely to the ultimate circuit pattern, at least not when a conventional block-out mask is employed for a second exposure on the resist film in concert with a first exposure made using a an alternating-aperture PSM. Such second exposures erase anomalies due to phase-conflicts. All these tools and strategies developed for conventional masks, phase-shifting or not, can be adapted for use in the production and use of the mask of the present invention.

A specific example of the mask of the present invention involves a grating index pattern. The index pattern is a 180° phase shifting 1-D or 2-D grating system created by scanning the photosensitive film or by exposing it using a phase mask. The grating pitch can be lower than 300 nm, and may be as short as 200 nm. These low pitch gratings can be used for creating very dense sub-wavelength features. A mask of the present invention may have a photosensitive film having such grating index patterns embedded therein. Such mask can be used in conjunction with trim mask and/or chrome binary masks via multiple exposure to create desired image patterns on an image-receiving substrate, such as a wafer. The trim mask can be a phase-shifting trim mask produced using the method of the present invention, or a conventional chrome trim mask. Advantageously, an additional feature P₃ formed by chrome or other weak phase shifting materials is formed atop the photosensitive mask substrate in which the grating is formed. An apparent advantage of this type of composite mask is that multiple exposure may be avoided or at least exposure steps can be reduced.

The following non-limiting examples further illustrate the present invention.

### EXAMPLES

In these examples, GeO₂—SiO₂ binary films or B₂O₃—GeO₂—SiO₂ ternary films were deposited on a silica substrate and tested.

The films were deposited using a STS Multiplex PECVD system. This system is a parallel plate reactor where the precursor gases enter through an array of holes in the top electrode (showerhead), and the sample rests on the bottom electrode (platen). Both electrodes are heated, typically to 250° C. (top) and 300° C. (bottom). The system is pumped with a roots blower and roughing pump, and a plasma is formed with either or both a 380 kHz and 13.56 MHz RF generators and matching network. The system can be configured so that either generator can drive the upper electrode (showerhead), while only the low frequency generator can drive the platen. Available process gases are 5% silane (SiH₄) in argon, 2% germane (GeH₄) in argon, nitrous oxide (N₂O), ammonia (NH₃), tetrafluoromethane (CF₄), oxygen (O₂), nitrogen (N₂), helium (He), argon (Ar), tetraethoxysilane (TEOS), tetramethoxygermane (TMOG), trimethylborate (TMB), and trimethylphosphite (TMPi). The refractive index and film thickness were determined with a prism coupling system. Annealing was performed either in a large thermcraft furnace with a 6″ quartz tube, water-cooled aluminum end collars with helium, or oxygen ambients, or in a box furnace (CM Rapid Temp furnace, MoSi₂ elements) in air. Elemental analysis was performed by using electron microprobe (EMPA). UV-Visible spectra were recorded using a Cary 3E spectrophotometer. Index changes were measured by exposing a grating on the film, and measuring the grating diffraction in transmission with a 632 nm laser. Detection limit for 20 μm thick film is estimated to be Δn≈1.0·10⁻⁴.

### Examples 1-6

Sample films A, B, C, D, E, F and G were created in these examples. TMOG was used as the germanium source along with TEOS, TMB, and TMPi as silicon, boron, and phosphorous sources to deposit six ˜20 μm thick SiO₂—GeO₂—B₂O₃—P₂O₅ films. Complete deposition parameters are listed in TABLE 1. These films were diced in half, and one half was overcladded using the deposition parameters listed in TABLE 2. Both halves were diced into 1×2 cm pieces, and pieces from both the bare half and the overcladded half were annealed and the UV-Vis spectra recorded. Terinary SiO₂—GeO₂—B₂O₃ film samples A, B and C had a slight brown tint as deposited, but became clear after annealing at 1000° C. in He, or above 800° C. in O₂ or above air. Films containing P₂O₅ of samples D, E and F were clear as deposited, and remained clear after annealing.

In FIGS. 9 and 10 we show the absorption spectrum of terinary film sample A indicating the presence of the GeODC in films. The absorption structure is stabilized by post-thermal treatments above 900° C. as shown from overlapping of the spectrum. The sharp spectral feature at 240-nm is the signature of the GeODC mentioned above. The strength of this band is estimated to be 10³ db/mm. As a reference in OV-prepared fibers it is the order of 40 db/mm and in IV-prepared fibers it is 400 db/mm. The concentration of the defect is seen to diminish with very high temperature (1200° C.) annealing in an oxidizing ambient.

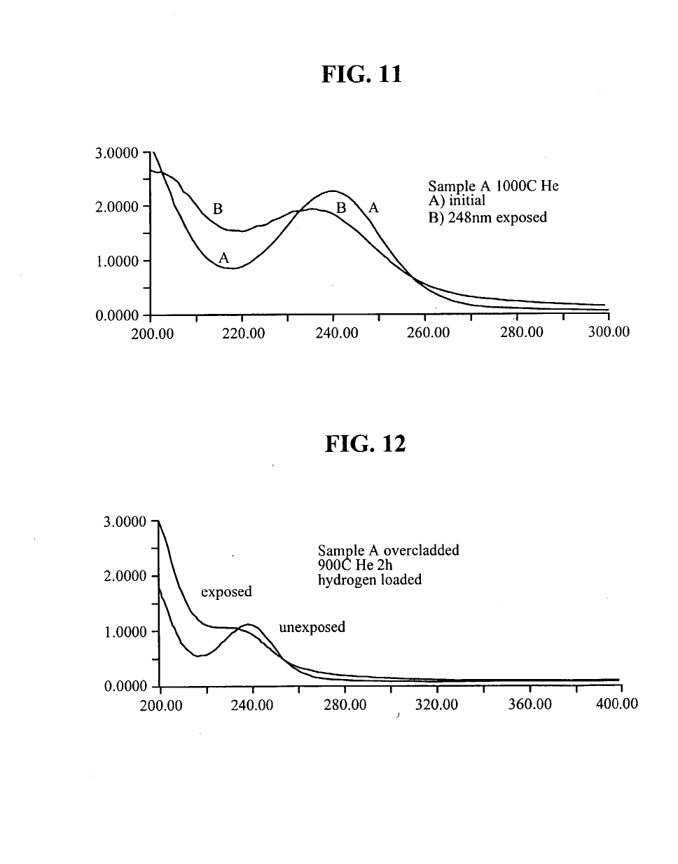

FIG. 11 shows the result of the film of sample A annealed at 1000° C. in He after the film was exposed to 248-nm excimer light at a fluence of 53 mJ/cm² for 45 minutes. One can see from the comparison to the spectrum of the unexposed state that the GeODC absorption feature is bleached. FIG. 12 shows the same film after deposition of a top cladding layer (20 μm of silica), annealing at 900° C. in He, and hydrogen loading (parameters). The bleaching is even more extensive in the hydrogen loaded film.

Diffraction gratings were written in the films using 248-nm excimer light at 42 mJ/cm² for anywhere from 30-60 minutes. The index change estimated to be 1.0×10⁴ without H₂ loading, and 2.7×10⁴ with H₂ loading.

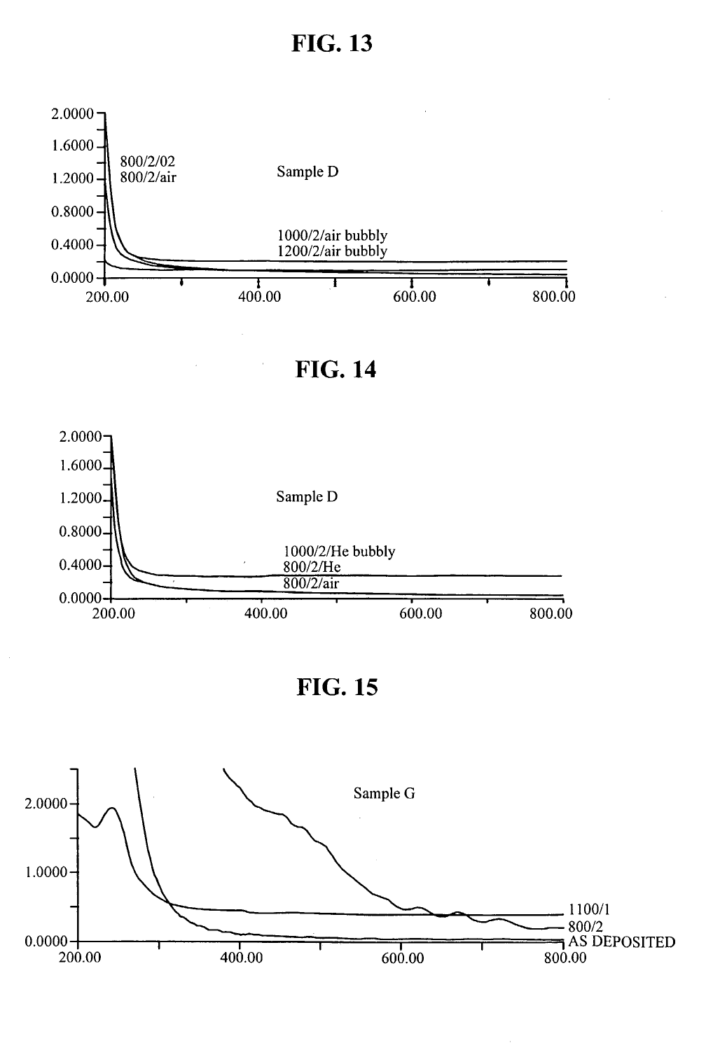

TABLE 3 summarizes the composition, GeODC band strength, and observed index change for all six samples A, B, C, D, E and F. Terinary SiO₂—GeO₂—B₂O₃ films were observed to have large 240 nm absorption characteristic of the GeODC. In contrast, the terinary SiO₂—GeO₂—P₂O₅ film and two quaternary SiO₂—GeO₂—B₂O₃—P₂O₅ films were observed to have very weak absorption. In FIGS. 13 and 14 we show the absorption spectrum of film sample D indicating little or no GeODC. Index changes were larger where GeODC strength was higher, except in the case of sample F which exhibited a large index change after hydrogen loading without formation of the GeODC.

### Example 7

A sample G film was created in this example. TMOG was used as the germanium source along with TEOS as silicon source to deposit a 14 μm thick binary film. Complete parameters are listed in TABLE 4. The film had a brown tint as deposited. The color darkened after annealing at 800° C. in air, but became lighter after annealing at 1000° C. in air. In FIG. 15 we show the absorption spectrum indicating the presence of the GeODC in films.

### Example 8

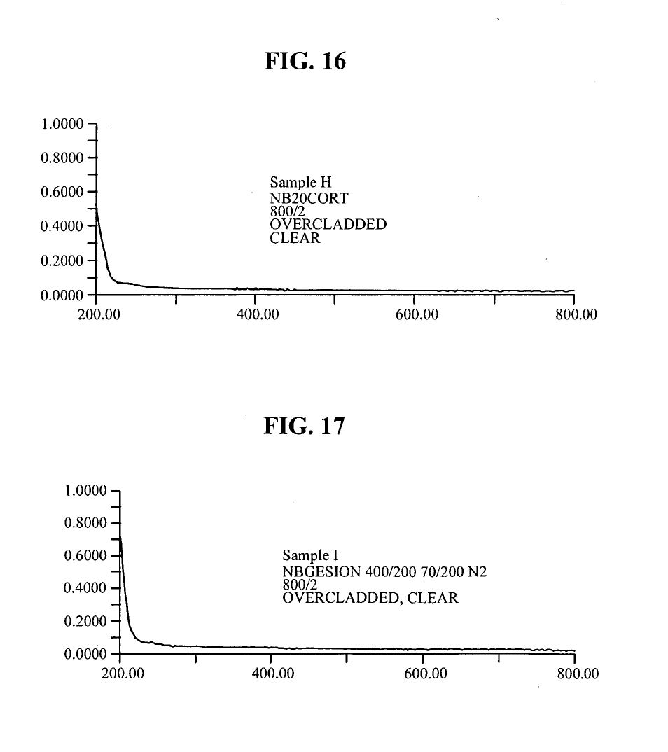

A 10 μm thick binary SiO₂—GeO₂ sample H film was deposited using silane and germane with the parameters are listed in TABLE 5. Film composition is estimated to be 34 wt % GeO₂. The film was clear as deposited and after annealing. In FIG. 16 we show the absorption spectrum of this film indicating very low or no 240 nm absorption characteristic of a GeODC.

### Example 9

A ˜10 μm thick nitrogen doped SiO₂—GeO₂ sample I film was deposited using silane and germane with the parameters are listed in TABLE 6. Film composition is estimated to be 25.0 wt % GeO₂. The film was clear as deposited and after annealing. In FIG. 17 we show the absorption spectrum of this film indicating very low or no 240 nm absorption characteristic of a GeODC.

TABLE 1

| | | | Temperature | | | | | | | | |
|---|---|---|---|---|---|---|---|---|---|---|---|
| | | RF | | Shower | | | | | | | |
| Example | Sample | 380 kHz | Platen | head | Pressure | Time | O₂ | TEOS | TMOG | TMB | TMPi |
| No. | No. | (W) | (° C.) | (° C.) | (mTorr) | (min) | (sccm) | (sccm) | (sccm) | (sccm) | (sccm) |
| 1 | A | 600 | 300 | 250 | 600 | 60 | 1000 | 40 | 3 | 15 | 0.0 |
| 2 | B | 600 | 300 | 250 | 600 | 60 | 1000 | 40 | 4 | 10 | 0.0 |
| 3 | C | 600 | 300 | 250 | 600 | 60 | 1000 | 40 | 3 | 20 | 0.0 |
| 4 | D | 600 | 300 | 250 | 600 | 60 | 1000 | 40 | 3 | 12 | 1.8 |
| 5 | E | 600 | 300 | 250 | 600 | 60 | 1000 | 40 | 3 | 0 | 1.5 |
| 6 | F | 600 | 300 | 250 | 600 | 60 | 1000 | 40 | 5 | 10 | 1.0 |

TABLE 2

| RF | Temperature | | | | | | |
|---|---|---|---|---|---|---|---|
| 380 kHz | Platen | Showerhead | Pressure | Time | 5% SiH₄ | N₂O | N₂ |
| (W) | (° C.) | (° C.) | (mTorr) | (min) | (sccm) | (sccm) | (sccm) |
| 462 | 300 | 250 | 503 | 105 | 400 | 2000 | 700 |

Note:
Conditional common for all samples A, B, C, D, E and F

TABLE 3

| | | | | | GeODC | | |
|---|---|---|---|---|---|---|---|
| Sample | SiO₂ | GeO₂ | B₂O₃ | P₂O₅ | strength | Δn | Δn |
| No. | (wt %) | (wt %) | (wt %) | (wt %) | (dB/mm) | no H₂ | H₂ loaded |
| A | 74.44 | 11.82 | 13.74 | 0.00 | 1.1E+03 | 1.00E−04 | 2.70E−04 |
| B | 73.87 | 16.71 | 9.42 | 0.00 | 9.7E+02 | 2.90E−04 | |
| C | 72.34 | 10.00 | 17.66 | 0.00 | 1.2E+03 | <1.0E−04 | 1.00E−04 |
| D | 72.52 | 12.64 | 10.81 | 4.03 | 0.0E+00 | | |
| E | 79.87 | 16.12 | 0.25 | 3.76 | 3.5E+01 | <1.0E−04 | <1.0E−04 |
| F | 69.10 | 19.88 | 8.69 | 2.33 | 1.4E+01 | <1.0E−04 | 2.00E−04 |

TABLE 4

| RF | Temperature | | | | | | |
|---|---|---|---|---|---|---|---|
| 380 kHz | Platen | Showerhead | Pressure | Time | O₂ | TEOS | TMOG |
| (W) | (° C.) | (° C.) | (mTorr) | (min) | (sccm) | (sccm) | (sccm) |
| 500 | 300 | 250 | 300 | 90 | 1000 | 40 | 4 |

Note:
Condition for sample G, example 7

TABLE 5

| | | RF | | Temperature | | | | | | | | |
|---|---|---|---|---|---|---|---|---|---|---|---|---|
| Example | Sample | 13.56 MHz | 380 kHz | Platen | Showerhead | Pressure | Time | 5% SiH₄ | 2% GeH₄ | N₂O | Carrier Gas | |
| No. | No. | (W, sh) | (W, pl) | (° C.) | (° C.) | (mTorr) | (min) | (sccm) | (sccm) | (sccm) | (sccm) | Annealing |
| 8 | H (Core) | 75 | 200 | 300 | 250 | 503 | 50 | 339 | 250 | 2000 | 520 He | 800/2 He |
| | | | | | | | | | | | | LPCVD |

Note:
Condition for sample H

TABLE 6

| | | RF | | Temperature | | | | | | | | |
|---|---|---|---|---|---|---|---|---|---|---|---|---|
| Example | Sample | 13.56 MHz | 380 kHz | Platen | Showerhead | Pressure | Time | 5% SiH₄ | 2% GeH₄ | N₂O | Carrier Gas | |
| No. | No. | (W, sh) | (W, pl) | (° C.) | (° C.) | (mTorr) | (min) | (sccm) | (sccm) | (sccm) | (sccm) | Annealing |
| 9 | I (Core) | 70 | 200 | 300 | 250 | 300 | 45 | 400 | 200 | 2000 | 684 N₂ | 800/2 He |
| | | | | | | | | | | | | LPCVD |

Note:
Conditions for Sample I

It will be apparent to those skilled in the art that various modifications and alterations can be made to the present invention without departing from the scope and spirit of the invention. Thus, it is intended that the present invention cover the modifications and variations of this invention provided they come within the scope of the appended claims and their equivalents.

What is claimed is:

1. A mask having a pattern P₀ transferable onto an image-receiving substrate when subjected to illumination radiation in a lithographic process, comprising a substrate S′ bearing on a surface thereof a UV photosensitive film S₁ consisting of (i) a UV induced index pattern P₁ and (ii) parts P₂ that are not UV induced, wherein the index pattern P₁ has a refractive index n₁ at the wavelength of the illumination radiation, the non-UV induced parts P₂ has a refractive index no at the wavelength of the illumination radiation, with n₁≠n₀, and n₀ and n₁ remain substantially unchanged when the mask is exposed to the illumination radiation during the lithographic process.

2. A mask in accordance with claim 1, wherein n₁−n₀>1×10⁻⁴.

3. A mask in accordance with claim 1, wherein the surface of the photosensitive film S₁ is substantially flat and smooth, and the index pattern P₁ is substantially free of stress and birefringence.

4. A mask in accordance with claim 1, wherein the index pattern P₁ has a thickness d chosen to create a near 180° phase-shift of the illumination radiation used in the lithographic process with respect to the non-UV induced parts P₂.

5. A mask in accordance with claim 4, wherein the index pattern P₁ has an edge with a tapering gradient in terms of phase shift amount.

6. A mask in accordance with claim 1, wherein the index pattern P₁ has an arbitrary distribution of phase shift amount.

7. A mask in accordance with claim 1, wherein the index pattern P₁ is a grating having a pitch of less than 300 nm.

8. A mask in accordance with claim 7, wherein the thickness of the index pattern P₁ is chosen to create a 180° phase shift of the illumination radiation during the lithographic process with respect to the non-UV induced parts P₂.

9. A mask in accordance with claim 1 comprising, above the film S₁, pattern features P₃ formed by layers of materials opaque or attenuating to the illumination radiation used in the lithographic process.

10. A mask in accordance with claim 9, wherein at least part of features P₃ is formed by Cr or modified Cr.

11. A mask in accordance with claim 9, wherein at least part of features P₃ is formed by attenuating material chosen to have a refractive index and thickness to create a 180° phase shift of the illumination radiation with respect to the ambient atmosphere in which the mask is placed during the lithographic process.

12. A mask in accordance with claim 9, wherein the features P₂ and P₃, when transferred together to the image-receiving substrate during the lithographic process, supplement and correct each other to form the desired image on the image-receiving substrate.

13. A mask in accordance with claim 1, wherein the substrate S′ is fused silica plate having flat surfaces, and the film S₁ is formed by a boro-germano-silicate glass having a composition consisting essentially, expressed in terms of weight percentage on an oxide basis, of: 0-20% of B₂O₃, 5-25% of GeO₂ and the remainder SiO₂.

14. A mask in accordance with claim 13, wherein the film is formed by a boro-germano-silicate glass having a composition consisting essentially, expressed in terms of weight percentage on an oxide basis, of: 0-10% of B₂O₃, 10-18% of GeO₂ and the remainder SiO₂.

15. A mask in accordance with claim 14, wherein the film is formed by a boro-germano-silicate glass having a composition consisting essentially, expressed in terms of weight percentage on an oxide basis, of: 5-10% of B₂O₃, 10-18% of GeO₂ and the remainder SiO₂.

16. A mask in accordance with claim 13, wherein the film S₀ has a GeODC level of at least 100 dB/mm at 240 nm.

17. A mask in accordance with any one of claims 13, wherein the film S₀ is further loaded with molecular hydrogen at a level of at least 10¹⁸ molecules/cm³.

18. A process for making a mask having a pattern P₀ transferable onto an image-receiving substrate when subjected to illumination radiation in a lithographic process, comprising the following steps:
(a) providing a substrate S′ transparent to the lithographic wavelength of the lithographic process in which the mask is used;
(b) depositing on a surface of S′ a UV photosensitive film S₀ having a refractive index n₀ at the wavelength of the illumination radiation to which the mask is subjected to during the lithographic process, said film S₀ having a lower surface bonding to the substrate S′, and an upper surface opposite to the lower surface;
(c) selectively exposing part of the film S₀ to UV radiation of less than 280 nm with an effective fluence for an effective amount of time, whereby producing a film S₁ consisting of (i) a UV induced index pattern P₁ having a refractive index n₁, with n₀≠n₁, and (ii) parts P₂ that are not UV induced having a refractive index n₀; and
(d) optionally, forming additional pattern features above the upper surface of the film S₀ or S₁ by depositing films of materials opaque or attenuating to the illumination radiation.

19. A process in accordance with claim 18, wherein in step (b), the film is annealed after deposition.

20. A process in accordance with claim 18, wherein in step (c), the UV induced index pattern P₁ is created substantially without compaction of film S₀, the pattern P₁ is substantially free of stress and birefringence, and the film S₁ having the induced index pattern P₁ has a substantially flat and smooth upper surface.

21. A process in accordance with claim 18, wherein in step (c), the fluence and wavelength of the UV radiation used to pattern the film S₀, as well as the exposure time are chosen such that the thickness d and refractive index n₁ of index pattern P₁ meet the following requirement:
d/(n₁−n₀)≈λ/2
where λ is the wavelength of the illumination radiation used in the lithographic process, thereby the pattern P₁ creates a near 180° phase shift of the illumination radiation with respect to the non-UV induced parts P₂.

22. A process in accordance with claim 18, wherein in step (c), the fluence or the UV radiation used to pattern the film S₀ and/or exposure time are chosen such that the thickness of the edge portion of the index pattern P₁ has a tapering gradient in terms of phase shift amount.

23. A process in accordance with claim 16, wherein the fluence of the UV radiation for patterning the film S₀ is adjusted by tuning the fluence of the radiation source.

24. A process in accordance with claim 18, wherein the fluence of the UV radiation for patterning the substrate S₀ is adjusted by using gradient attenuating mask.

25. A process in accordance with claim 18, wherein in step (c), a contact or proximity phase mask is used for selectively exposing the film S₀ or S₁ to the patterning UV radiation.

26. A process in accordance with claim 18, wherein step (d) comprises depositing a film of a material opaque or attenuating to the illumination radiation used in the lithographic process above the upper surface of S₀ or S₁, depositing a photoresist on top of the opaque/attenuating film, exposing the photoresist, developing the exposed photoresist, selectively etching the opaque/attenuating film, followed by stripping the remaining photoresist, whereby additional pattern features of the opaque/attenuating material are formed.

27. A process in accordance with claim 18, wherein in step (d), where an attenuating material is used to form the additional features, its refractive index at the wavelength of the illumination radiation used in the lithographic process and its thickness are chosen such that the film creates a 180° phase shift of the illumination radiation with respect to the ambient atmosphere in which the mask is to be used.

28. A process in accordance with claim 18, wherein the transparent substrate S′ in step (a) is a plate having flat surfaces made of a material selected from fused silica, doped fused silica and low thermal expansion glass-ceramics, and the photosensitive film S₀ in step (b) is formed by a boro-germano-silicate glass having a composition consisting essentially, expressed in terms of weight percentage, of: 0-20% of B₂O₃, 5-25% of GeO₂ and the remainder SiO₂.

29. A process in accordance with claim 28, wherein the photosensitive film S₀ in step (b) is formed by a boro-germano-silicate film having a Ge oxygen deficiency center (GeODC) level of at least 100 dB/mm at 240 nm, and a composition consisting essentially, expressed in terms of weight percentage, of: 0-10% of B₂O₃, 10-18% of GeO₂, and the remainder SiO₂.

30. A process in accordance with claim 29, wherein the photosensitive film S₀ in step (b) is formed by a boro-germano-silicate film having a composition consisting essentially, expressed in terms of weight percentage on an oxide basis, of: 5-10% B₂O₃, 10-18% of GeO₂, and the remainder SiO₂.

31. A process in accordance with claim 28, wherein the film S₀ is further loaded with molecular hydrogen at a level of at least 10¹⁸ molecules/cm³.

32. A process in accordance with claim 29, wherein the boro-germano-silicate film S₀ is deposited by using plasma enhanced chemical vapor deposition (PECVD) method, wherein tetramethoxygermane (Ge(OCH₃)₄) is used as the source of germanium.

33. A process in accordance with claim 32, wherein tetraethoxysilane (Si(OCH₂CH₃)₄) and tetramethylboron (B(CH₃)₃) are used as the silicon and boron source, respectively.

34. A photosensitive boro-germano-silicate film having a GeODC level of at least 100 dB/mm at 240 nm and a refractive index n₀, which, upon being exposed to UV radiation having a wavelength less than 280 nm with a fluence of 50 mJ/cm², has a refractive index n₁, with n₀≠n₁, said glass having a composition consisting essentially, expressed in terms of weight percentage on an oxide basis, of: 0-25% of B₂O₃, 5-25% of GeO₂, and the remainder SiO₂.

35. A photosensitive film in accordance with claim 34 having a composition consisting essentially, expressed in terms of weight percentage on an oxide basis, of: 0-10% of B₂O₃, 10-18% of GeO₂, and the remainder SiO₂.

36. A photosensitive film in accordance with claim 35 having a composition consisting essentially, expressed in terms of weight percentage on an oxide basis, of: 5-10% of B₂O₃, 10-18% of GeO₂, and the remainder SiO₂.

37. A photosensitive film in accordance with claim 34, wherein upon exposure to the UV radiation having a wavelength less than 280 nm is substantially without compaction in the exposed area, and the exposed area is substantially free of stress and birefringence.

38. A photosensitive film in accordance with claim 34, further comprising loaded molecular H₂ at a level of at least 10¹⁸ molecules/cm³.

39. A plasma enhanced chemical vapor deposition (PECVD) process for depositing a photosensitive B₂O₃—GeO₂—SiO₂ film, wherein tetramethoxygermane is used as the germanium source.

40. A process in accordance with claim 39, wherein tetraethoxysilane and trimethylboron are used as the source of silicon and boron, respectively.

41. A process in accordance with claim 39, wherein the as deposited film is further subjected to annealing in N₂, inert gases, air, or oxygen.

42. A mask blank comprising a flat substrate S′ bearing a UV photosensitive film S₀ on a surface thereof, wherein
(I) the film S₀ has a refractive index n₀ at the wavelength of the radiation used in a lithographic process;
(II) upon selective exposure to UV radiation less than 280 nm at an effective fluence for an effective amount of time, an index pattern P₁ transferable to an image-receiving substrate when subjected to illumination radiation in a lithographic process can be formed within the film S₀, said index pattern P₁ having an integrated refractive index n₁, with n₁≠n₀; and
(III) n₀ and n₁ remain substantially the same when exposed to the illumination radiation used in the lithographic process.

43. A mask blank in accordance with claim 42, wherein the film S₀ when subjected to selective UV exposure having a wavelength low than 280 nm, is substantially without compaction and the induced index pattern P₁ is substantially free of stress and birefringence.

44. A mask blank in accordance with claim 42, wherein the substrate S′ is made of a material selected from fused silica, doped silica, low expansion optical glass-ceramic material.

45. A mask blank in accordance with claim 42, further comprising, above the film S₀, an additional film of material opaque or attenuating to the illumination radiation used in a lithographic process.

46. A mask blank in accordance with claim 45, wherein the additional film is formed by Cr and/or modified Cr.

47. A mask blank in accordance with claim 42, wherein the film S₀ is formed by a boro-germano-silicate glass having a composition consisting essentially, expressed in terms of weight percentage on an oxide basis, of: 0-20% of B₂O₃, 5-25% of GeO₂ and the remainder SiO₂.

48. A mask blank in accordance with claim 47, wherein the film S₀ is formed by a boro-germano-silicate glass having a composition consisting essentially, expressed in terms of weight percentage on an oxide basis, of: 0-10% of B₂O₃, 10-18% of GeO₂, and the remainder SiO₂.

49. A mask blank in accordance with claim 48, wherein the film S₀ is formed by a boro-germano-silicate glass having a composition consisting essentially, expressed in terms of weight percentage on an oxide basis, of: 5-10% of B₂O₃, 10-18% of GeO₂, and the remainder SiO₂.

50. A mask blank in accordance with claim 47, wherein the film is further loaded with molecular H₂ at a level of at least 10¹⁸ molecules/cm³.
